(19) United States
(12) Patent Application Publication
(10) Pub. No.: US 2012/0161988 A1
(43) Pub. Date: Jun. 28, 2012

(54) KEYBOARD

(76) Inventor: Chao-Lung Chang, Taoyuan (TW)

(21) Appl. No.: 13/337,281

(22) Filed: Dec. 26, 2011

(30) Foreign Application Priority Data
Dec. 27, 2010 (TW) 099225123

(51) Int. Cl. H03M 11/00

(52) U.S. Cl. 341/22

(57) ABSTRACT

A keyboard includes a base, a plurality of keyswitches, a transparent protective cover and a light emitting module. The keyswitches are disposed on the base and each keyswitch includes a transparent key cap. The transparent protective cover includes a plurality of hollow protruding portions. When the transparent protective cover is disposed on the base, each of the hollow protruding portions covers one of the transparent key caps. The light emitting module is selectively disposed on or below the base. The color of light emitted by the light emitting module is different from the color of the transparent protective cover.

### BACKGROUND OF THE INVENTION

1. Field of the Invention

The invention relates to a keyboard and, more particularly, to a keyboard having a transparent protective cover and a light emitting module, wherein the color of light emitted by the light emitting module is different from the color of the transparent protective cover.

2. Description of the Prior Art

A keyboard, which is the most common input device, can be found in variety of electronic equipments for users to input characters, symbols, numerals and so on. To prevent the keyboard from being damaged due to external object (e.g. water, dust, etc.), which may enter the keyboard through gaps between key caps, the prior art covers the gaps between the key caps with a protective cover so as to prevent the external object from entering the keyboard through the gaps between the key caps. Furthermore, some protective covers are made of transparent material so that these protective covers can be applied to a light keyboard. Accordingly, a user can cover the light keyboard with the protective cover while using the light keyboard and light emitted by a light emitting module of the light keyboard can be projected out of the projective cover. However, since the conventional protective cover is always colorless, light emitted by the light emitting module cannot show light-mixing effect through the protective cover when the conventional protective cover is covered on the light keyboard. In other words, visual effect of the light keyboard covered with the conventional protective cover is monotonous.

### SUMMARY OF THE INVENTION

Therefore, an objective of the invention is to provide a keyboard having a transparent protective cover and a light emitting module, wherein the color of light emitted by the light emitting module is different from the color of the transparent protective cover, so as to solve the aforesaid problems.

According to an embodiment of the invention, a keyboard comprises abase, a plurality of keyswitches, a transparent protective cover and a light emitting module. The keyswitches are disposed on the base and each of the keyswitches comprises a transparent key cap. The transparent protective cover comprises a plurality of hollow protruding portions. When the transparent protective cover is disposed on the base, each of the hollow protruding portions covers one of the transparent key caps. The light emitting module is selectively disposed on or below the base. A color of light emitted by the light emitting module is different from a color of the transparent protective cover. In this embodiment, the transparent protective cover maybe divided into a plurality of areas and colors of the areas are different from each other.

As mentioned in the above, since the color (e.g. yellow) of the transparent protective cover of the invention is different from the color (e.g. blue) of light emitted by the light emitting module, the light emitted by the light emitting module can show light-mixing effect through the transparent protective cover (e.g. blue light can be converted into green light through yellow protective cover). Furthermore, since the transparent protective cover of the invention can be divided into a plurality of areas with different colors (e.g. two areas with yellow and red), light emitted by the light emitting module can show different light-mixing effects through different areas of the transparent protective cover. Accordingly, a user can change the color of the transparent protective cover according to his or her preferences so as to improve visual effect of the keyboard of the invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a keyboard according to an embodiment of the invention.

FIG. 2 is a partial exploded view illustrating the keyboard shown in FIG. 1.

FIG. 3 is a cross-sectional view illustrating the keyboard along line X-X shown in FIG. 1.

FIG. 4 is a schematic diagram illustrating a transparent protective cover according to another embodiment of the invention.

FIG. 5 is a cross-sectional view illustrating the transparent protective cover shown in FIG. 3 replaced by a transparent protective cover according to another embodiment of the invention.

FIG. 6 is a partial cross-sectional view illustrating a keyboard according to another embodiment of the invention.

### DETAILED DESCRIPTION

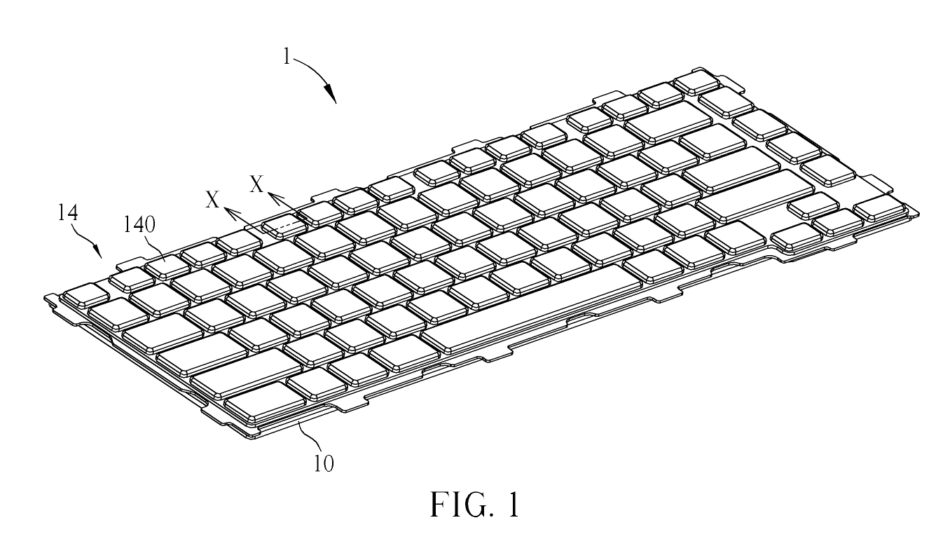

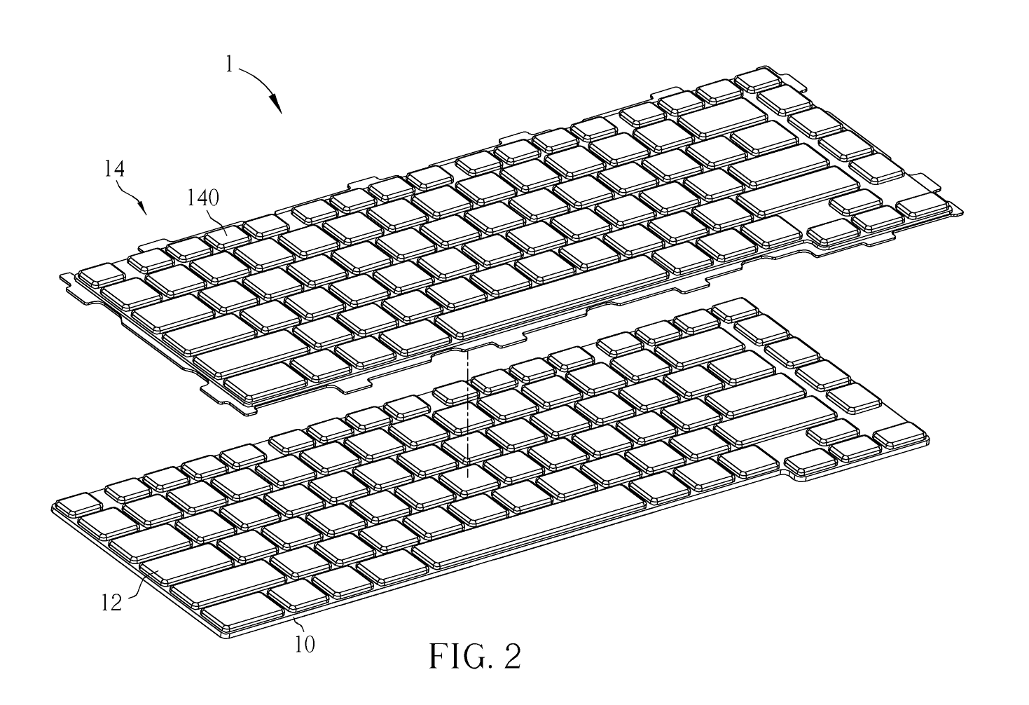

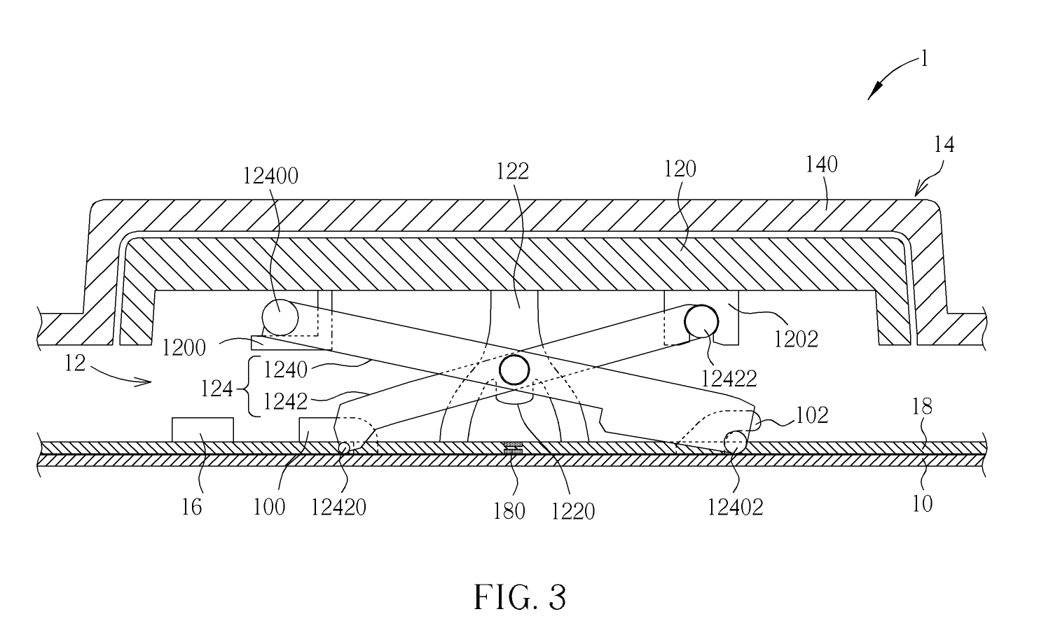

Referring to FIGS. 1 to 3, FIG. 1 is a schematic diagram illustrating a keyboard 1 according to an embodiment of the invention, FIG. 2 is a partial exploded view illustrating the keyboard 1 shown in FIG. 1, and FIG. 3 is a cross-sectional view illustrating the keyboard 1 along line X-X shown in FIG. 1. As shown in FIGS. 1 to 3, the keyboard 1 comprises a base 10, a plurality of keyswitches 12, a transparent protective cover 14 and a light emitting module 16. The keyswitches 12 are disposed on the base 10 and used for a user to press so as to execute desired function correspondingly. In this embodiment, the transparent protective cover 14 maybe made of, but not limited to, rubber. In other words, the transparent protective cover 14 just has to be made of transparent material.

As shown in FIG. 3, the keyboard 1 further comprises a circuit board 18 disposed between the base 10 and the keyswitch 12, wherein the circuit board 18 has a plurality of switches 180 (only one switch 180 is shown in FIG. 3) and the keyswitch 12 is corresponding to the switch 180. In practical applications, the circuit board 18 may be, but not limited to, a membrane circuit board and the switch 180 may be, but not limited to, a membrane switch or other trigger-type switch. Furthermore, the keyswitch 12 comprises a transparent key cap 120, a resilient member 122 and a lift support device 124, wherein the resilient member 122 and the lift support device 124 are disposed between the base 10 and the transparent key cap 120. In this embodiment, the transparent key cap 120 is made of transparent material. The resilient member 122 may be, but not limited to, a rubber dome. The resilient member 122 is used to provide elastic force while the transparent key cap 120 moves upward and downward with respect to the case 10. Moreover, the resilient member 122 has a trigger portion 1220. When the transparent key cap 120 of the keyswitch 12 is pressed, the trigger portion 1220 of the resilient member 122 triggers the switch 180 of the circuit board 18, so as to execute desired function correspondingly.

In this embodiment, the transparent key cap 120 may have a first sliding groove 1200 and a first engaging groove 1202 and the base 10 may have a second sliding groove 100 and a second engaging groove 102. The lift support device 124 may comprise a first support member 1240 and a second support member 1242, wherein the first support member 1240 is pivotally connected to the second support member 1242. The first support member 1240 may have a first sliding portion 12400 and a first pivoting portion 12402. The second support member 1242 may have a second sliding portion 12420 and a second pivoting portion 12422. The first sliding portion 12400 is slidably disposed in the first sliding groove 1200 and the first pivoting portion 12402 is rotatably disposed in the second engaging groove 102. The second sliding portion 12420 is slidably disposed in the second sliding groove 100 and the second pivoting portion 12422 is rotatably disposed in the first engaging groove 1202. Accordingly, when the transparent key cap 120 of the keyswitch 12 is pressed, the transparent key cap 120 will move toward the base 10 along with the lift support device 124.

As shown in FIG. 3, the light emitting module 16 is disposed on the base 10 and corresponding to the keyswitch 12. In this embodiment, the light emitting module 16 may be a light emitting diode and is electrically connected the circuit board 18. The light emitting module 16 is used for providing light for the keyswitch 12. Furthermore, the transparent protective cover 14 comprises a plurality of hollow protruding portions 140. When the transparent protective cover 14 is disposed on the base 10, each of the hollow protruding portions 140 covers one of the transparent key caps 120 of the keyswitches 12. In this embodiment, a color of light emitted by the light emitting module 16 is different from a color of the transparent protective cover 14 so that the light emitted by the light emitting module 16 can show light-mixing effect through the transparent protective cover 14. For example, if the color of the transparent protective cover 14 is yellow and the color of light emitted by the light emitting module 16 is blue, the blue light emitted by the light emitting module 16 will be converted into green light through the yellow transparent protective cover 14.

Moreover, the invention may further make the colors of the transparent key caps 120 of some keyswitches 12 to be different from the color of the transparent protective cover 14 and/or different from the color of light emitted by the light emitting module 16, so as to increase variability of light-mixing effect.

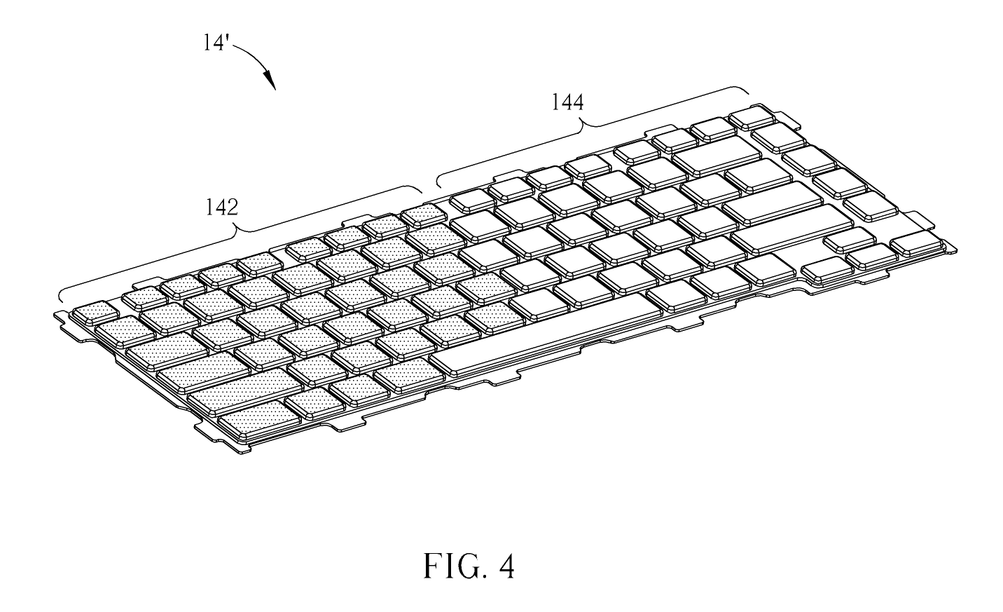

Referring to FIG. 4, FIG. 4 is a schematic diagram illustrating a transparent protective cover 14′ according to another embodiment of the invention. The transparent protective cover may be divided into a plurality of areas and colors of the areas are different from each other. As shown in FIG. 4, the main difference between the transparent protective cover 14′ and the aforesaid transparent protective cover 14 is that the transparent protective cover 14′ is divided into two areas 142, 144, and the color of the area 142 is different from the color of the area 144. For example, the area 142 may be yellow and the area 144 may be red. After replacing the transparent protective cover 14 by the transparent protective cover 14′, light emitted by the light emitting module 16 will show different light-mixing effects through the areas 142, 144 of the transparent protective cover 14′. Accordingly, a user can change the color of the transparent protective cover according to his or her preferences so as to improve visual effect of the keyboard of the invention. It should be noted that the transparent protective cover 14′ maybe also divided into more than two areas according to practical applications and colors of the areas are different from each other. In other words, the transparent protective cover of the invention is not limited to the embodiment shown in FIG. 4.

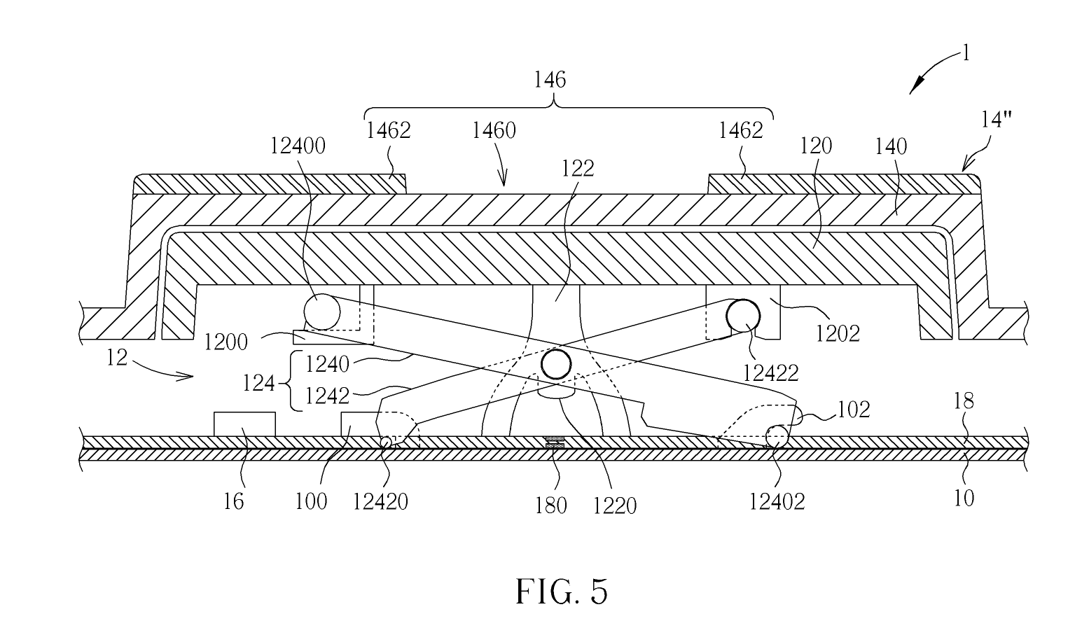

Referring to FIG. 5, FIG. 5 is a cross-sectional view illustrating the transparent protective cover 14 shown in FIG. 3 replaced by a transparent protective cover 14″ according to another embodiment of the invention. As shown in FIG. 5, the main difference between the transparent protective cover 14″ and the transparent protective cover is that the transparent protective cover 14″ further comprises a plurality of pattern layers 146 (only one pattern layer 146 is shown in FIG. 5), wherein the pattern layer 146 is formed the hollow protruding portion 140 comprises a transparent portion 1460 and a non-transparent portion 1462. In practical applications, the pattern layer 146 may be character, symbol or numeral for a user to select. The pattern layer 146 maybe non-transparent ink and formed on the hollow protruding portion 140 by a printing process. In another embodiment, the pattern layer 146 may be formed on the hollow protruding portion 140 by an ink spraying process first, and then parts of the pattern layer 146 are removed by a laser marking process so as to form the transparent portion 1460. In this embodiment, a color of light emitted by the light emitting module 16 is also different from a color of the transparent protective cover 14″. Therefore, the light emitted by the light emitting module 16 can show light-mixing effect through the transparent portion 1460 of the pattern layer 146 of the transparent protective cover 14″ and show character, symbol or numeral correspondingly for a user to select. It should be noted that the same elements in FIG. 5 and FIG. 3 are represented by the same numerals, so the repeated explanation will not be depicted herein again.

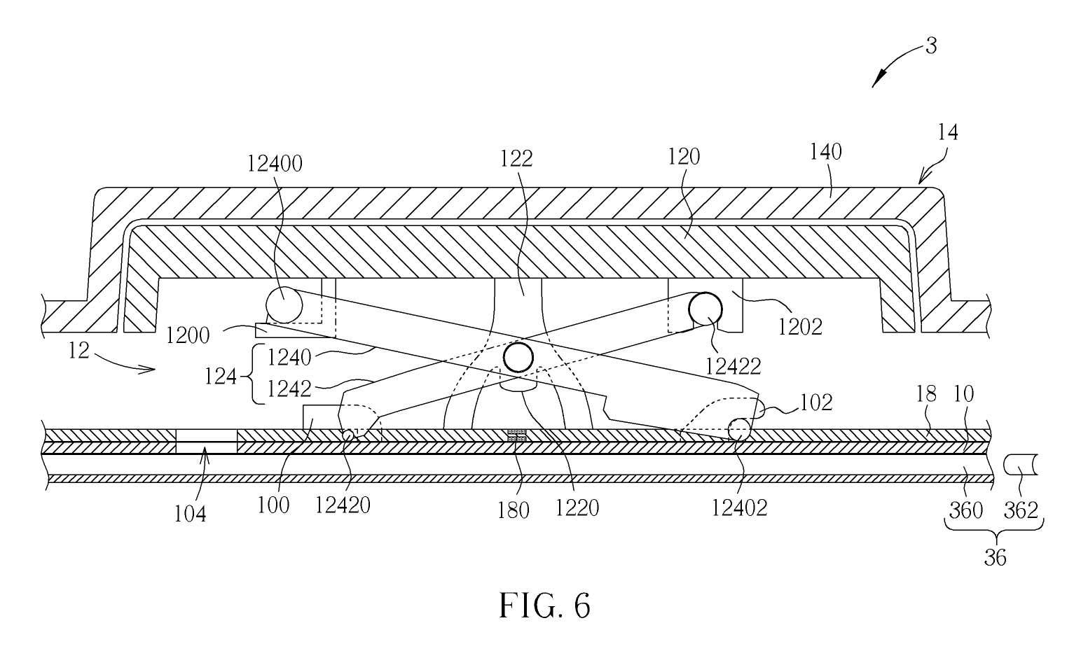

Referring to FIG. 6, FIG. 6 is a partial cross-sectional view illustrating a keyboard 3 according to another embodiment of the invention. As shown in FIG. 6, the main difference between the keyboard 3 and the aforesaid keyboard 1 is that the light emitting module 36 of the keyboard 3 comprises a light guiding plate 360 and a light emitting diode 362. In this embodiment, the light guiding plate 360 is disposed below the base 10 and the light emitting diode 362 is disposed adjacent to the light guiding plate 360. The base 10 has a hole 104 corresponding to the transparent key cap 120. Light emitted by the light emitting diode 362 can be projected to the transparent key cap 120 through the light guiding plate 360 and the hole 104. It should be noted that the same elements in FIG. 6 and FIG. 3 are represented by the same numerals, so the repeated explanation will not be depicted herein again.

As mentioned in the above, since the color (e.g. yellow) of the transparent protective cover of the invention is different from the color (e.g. blue) of light emitted by the light emitting module, the light emitted by the light emitting module can show light-mixing effect through the transparent protective cover (e.g. blue light can be converted into green light through yellow protective cover). Furthermore, since the transparent protective cover of the invention can be divided into a plurality of areas with different colors (e.g. two areas with yellow and red), light emitted by the light emitting module can show different light-mixing effects through different areas of the transparent protective cover. Accordingly, a user can change the color of the transparent protective cover according to his or her preferences so as to improve visual effect of the keyboard of the invention. Moreover, the invention may form the pattern layer, which represents character, symbol or numeral, on the transparent protective cover corresponding to each keyswitch for a user to select.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A keyboard comprising:
a base;
a plurality of keyswitches disposed on the base, each of the keyswitches comprising a transparent key cap;
a transparent protective cover comprising a plurality of hollow protruding portions, wherein when the transparent protective cover is disposed on the base, each of the hollow protruding portions covers one of the transparent key caps; and
a light emitting module selectively disposed on or below the base, a color of light emitted by the light emitting module is different from a color of the transparent protective cover.

2. The keyboard of claim 1, wherein the transparent protective cover is divided into a plurality of areas and colors of the areas are different from each other.

3. The keyboard of claim 1, wherein the transparent protective cover further comprises a plurality of pattern layers, each of the pattern layers is formed one of the hollow protruding portions, and each of the pattern layers comprises a transparent portion and a non-transparent portion.

4. The keyboard of claim 1, wherein the light emitting module comprises a plurality of light emitting diodes disposed on the base and each of the light emitting diodes is corresponding to one of the keyswitches.

5. The keyboard of claim 1, wherein the light emitting module comprises a light guiding plate and a light emitting diode, the light guiding plate is disposed below the base, the light emitting diode is disposed adjacent to the light guiding plate, the base has a plurality of holes corresponding to the transparent key caps, and light emitted by the light emitting diode is projected to the transparent key caps through the light guiding plate and the holes.

6. The keyboard of claim 1, wherein the transparent protective cover is made of rubber.

7. The keyboard of claim 1, further comprising a circuit board disposed between the base and the keyswitches, wherein the circuit board has a plurality of switches and each of the keyswitches is corresponding to one of the switches.

8. The keyboard of claim 1, wherein each of the keyswitches comprises a resilient member and a lift support device, the resilient member and the lift support device are disposed between the base and the transparent key cap.

9. The keyboard of claim 8, wherein the transparent key cap has a first sliding groove and a first engaging groove, the base has a second sliding groove and a second engaging groove, the lift support device comprises:
a first support member having a first sliding portion and a first pivoting portion, the first sliding portion being slidably disposed in the first sliding groove, the first pivoting portion being rotatably disposed in the second engaging groove; and
a second support member pivotally connected to the first support member, the second support member having a second sliding portion and a second pivoting portion, the second sliding portion being slidably disposed in the second sliding groove, the second pivoting portion being rotatably disposed in the first engaging groove.

10. The keyboard of claim 8, wherein the resilient member is a rubber dome.
